(19) United States
(12) Patent Application Publication
(10) Pub. No.: US 2026/0139374 A1
(43) Pub. Date: May 21, 2026

(54) GROWTH OF GATE OXIDE LAYER WITH SILICON NITRIDE AND CONVERSION

(71) Applicant: Applied Materials, Inc., Santa Clara, CA (US)

(72) Inventors: Fredrick FISHBURN, Aptos, CA (US); Raghuveer Satya MAKALA, Santa Clara, CA (US); Zhijun CHEN, San Jose, CA (US); Hao ZHANG, San Diego, CA (US); Johanes F. SWENBERG, Los Gatos, CA (US); Christopher S. OLSEN, Fremont, CA (US); Hansel LO, San Jose, CA (US); Kristopher Mikael KOSKELA, San Jose, CA (US); Hoi Sung CHUNG, Sunnyvale, CA (US); Chang Seok KANG, San Jose, CA (US)

(21) Appl. No.: 19/344,726

(22) Filed: Sep. 30, 2025

Related U.S. Application Data
(60) Provisional application No. 63/723,178, filed on Nov. 21, 2024.

(51) Int. Cl. C23C 16/455; C23C 16/04; C23C 16/34; C23C 16/40

(52) U.S. Cl. CPC C23C 16/45536; C23C 16/045; C23C 16/345; C23C 16/402; C23C 16/45553

(57) ABSTRACT

A method for forming an oxide layer includes forming at least a portion of a gate oxide layer on inner surfaces of an opening, forming a silicon nitride capping layer on the portion of the gate oxide layer, and performing a conversion process to at least partially oxidize the silicon nitride capping layer, forming a nitrogen-doped gate oxide layer.

### CROSS-REFERENCE TO RELATED APPLICATIONS

This application claims priority to U.S. Provisional Application Ser. No. 63/723,178 filed Nov. 21, 2024, which is herein incorporated by reference in its entirety.

### BACKGROUND

### Field

Embodiments described herein generally relate to semiconductor device fabrication, and more particularly, to methods of forming a high quality thin oxide layer in a high aspect ratio semiconductor structure.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, lateral channel structures used in 3D dynamic random access memory (DRAM) devices and vertical channel structures used in 4F² DRAM devices may have an aspect ratio of 6:1, 10:1, 20:1, or more and require a gate oxide layer that is thin and reliable.

In such structures, gate oxides may incorporate nitrogen to form electrical and diffusion barriers. Conventional methods for incorporating nitrogen into a gate oxide, which are either delivering nitrogen to an amorphous silicon oxide (SiO₂) film or delivering nitrogen to an interface between silicon (Si) and silicon oxide (SiO₂), only allow low and non-uniform nitrogen incorporation in gate oxides in high-aspect ratio structures.

Thus, there is a need for improved processes for forming a thin high quality oxide layer allowing control over nitride incorporation in the gate oxides.

### SUMMARY

Embodiments of the present disclosure provide a method for forming an oxide layer. The method includes forming at least a portion of a gate oxide layer on inner surfaces of an opening, forming a silicon nitride capping layer on the portion of the gate oxide layer, and performing a conversion process to at least partially oxidize the silicon nitride capping layer, forming a nitrogen-doped gate oxide layer.

Embodiments of the present disclosure also provide a method for forming an oxide layer. The method includes forming at least a portion of a gate oxide layer on inner surfaces of an opening, including forming protective interlayer oxide on the inner surfaces of the opening, forming a bi-layer of a bottom nitrogen-rich silicon nitride layer on the protective interlayer oxide and a top silicon nitride layer on the bottom nitrogen-rich silicon nitride layer, and oxidizing the bi-layer.

Embodiments of the present disclosure further provide a method for forming an oxide layer. The method includes forming at least a portion of a gate oxide layer on inner surfaces of an opening, including forming protective interlayer oxide on the inner surfaces of the opening, forming a hybrid layer of a bottom silicon nitride layer on the protective interlayer oxide and a top silicon oxide layer on the bottom silicon nitride layer, and oxidizing the hybrid layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a substrate processing system according to one embodiment.

FIG. 2 is a process flow diagram of a method of forming an oxide layer in a semiconductor structure according to one embodiment.

FIGS. 3A, 3B, 3B', 3C, 3D, and 3E are schematic views of a semiconductor structure according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein are directed to methods of forming a high quality nitrogen-doped thin oxide layer in a semiconductor device, such as lateral channel structures used in 3D dynamic random access memory (DRAM) devices and vertical channel structures used in 4F² DRAM devices. A nitrogen-doped thin oxide layer that may be used as a gate oxide layer in such devices may be formed by first depositing a substantial portion of a gate oxide layer, depositing a silicon nitride layer on the substantial portion of the gate oxide layer, and then oxidizing the silicon nitride layer by a conversion process. The silicon nitride layer provides a nitrogen source to the gate oxide layer. During the oxidation of the silicon nitride layer, nitrogen incorporation level and profile can be engineered as required. The incorporated nitrogen in the gate oxide layer may act as electrical and diffusion barriers in subsequent process steps (e.g., metal electrode deposition on the gate oxide layer).

The methods described herein for forming a thin nitrogen-doped oxide layer may allow incorporation of nitrogen at a high level (e.g., more than 5% or 2%) into a gate oxide layer and provide the capability of selectively tuning a thickness and nitride incorporation distribution of an oxide layer. For example, a gate oxide layer formed on inner surfaces of a high aspect ratio opening can have a uniform nitrogen concentration or can have a controlled level of nitrogen concentration, if desired.

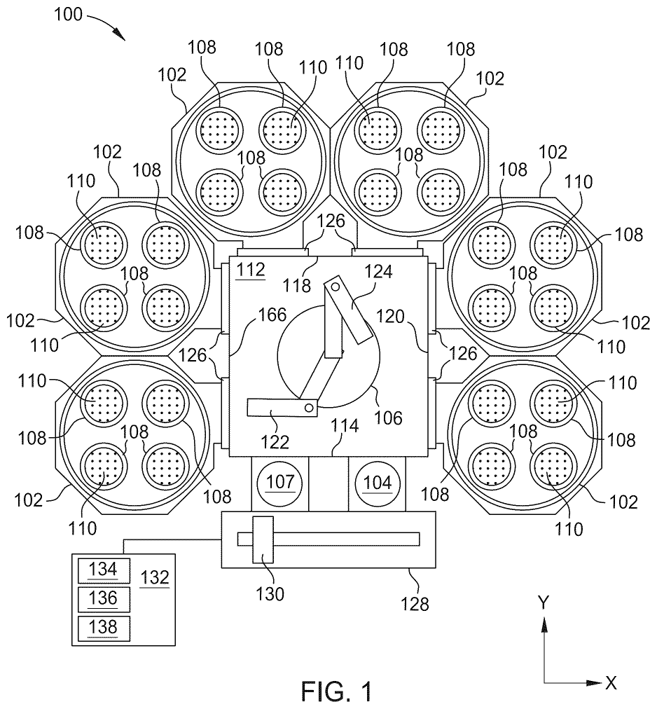

FIG. 1 shows a processing platform 100 in accordance with one or more embodiments of the disclosure. The embodiment shown in FIG. 1 is merely representative of one possible configuration and should not be taken as limiting the scope of the disclosure. For example, in some embodiments, the processing platform 100 has a different number of processing chambers 102, buffer stations 104 and/or robot 106 configurations different from the illustrated embodiment.

The processing chamber 102 includes a plurality of processing stations 108. The processing stations 108 are spatially separated in an interior volume 110 within the processing chamber 102. Each processing station 108 independently has a processing chamber temperature that can be different from the other processing station temperatures.

The processing stations 108 can be configured to perform any suitable process and provide any suitable process conditions. For example, a processing station 108 configured to operate as an atomic layer deposition (ALD) apparatus may have a showerhead or vortex type gas injector. Whereas, a processing station 108 configured to operate as a plasma station may have one or more electrode and/or grounded plate configuration to generate a plasma while allowing a plasma gas to flow toward the wafer. Suitable processing stations 108 include, but are not limited to, an inductively coupled plasma (ICP) process station, a capacitively coupled plasma (CCP) process station, an etch soak process station, a thermal process station, a microwave plasma station, a UV exposure station, a laser process station, a pumping chamber station, an annealing station, and a metrology station.

The exemplary processing platform 100 includes a central transfer station 112 which has a plurality of sides 114, 116, 118, 120. The central transfer station 112 shown has a first side 114, a second side 116, a third side 118 and a fourth side 120. Although four sides are shown, those skilled in the art will understand that there can be any suitable number of sides to the central transfer station 112 depending on, for example, the overall configuration of the processing platform 100. In some embodiments, the transfer station 112 has three sides, four sides, five sides, six sides, seven sides or eight sides.

The transfer station 112 has a robot 106 positioned therein. The robot 106 can be any suitable robot capable of moving a wafer during processing. In some embodiments, the robot 106 has a first arm 122 and a second arm 124. The first arm 122 and the second arm 124 can each be moved independently of the other arm. The first arm 122 and the second arm 124 can move in the X-Y plane and/or along the Z-axis. In some embodiments, the robot 106 includes a third arm (not shown) or a fourth arm (not shown). Each of the arms can move independently of other arms.

The embodiment illustrated includes six processing chambers 102 with two connected to each of the second side 116, the third side 118, and the fourth side 120 of the central transfer station 112. Each of the processing chambers 102 can be configured to perform different processes.

The processing platform 100 can also include one or more buffer stations 104 connected to the first side 114 of the central transfer station 112. The buffer stations 104 can perform the same or different functions. For example, the buffer stations 104 may hold a cassette of wafers which are processed and returned to the original cassette, or one of the buffer stations 104 may hold unprocessed wafers which are moved to the other buffer station 104 after processing. In some embodiments, one or more of the buffer stations 104 are configured to pre-treat, pre-heat or clean the wafers before and/or after processing.

The processing platform 100 may also include one or more slit valves 126 between the central transfer station 112 and any of the processing chambers 102. The slit valves 126 can open and close to isolate the interior volume 110 within the processing chamber 102 from the environment within the central transfer station 112. For example, if the processing chamber 102 generates plasma during processing, it may be helpful to close the slit valve 126 for that processing chamber 102 to prevent stray plasma from damaging the robot 106 in the central transfer station 112.

The processing platform 100 can be connected to a factory interface 128 to allow wafers or cassettes of wafers to be loaded into the processing platform 100. A robot 130 within the factory interface 128 can be used to move the wafers or cassettes into and out of the buffer stations 104. The wafers or cassettes can be moved within the processing platform 100 by the robot 106 in the central transfer station 112. In some embodiments, the factory interface 128 is a central transfer station 112 of another cluster tool (i.e., another multiple chamber processing platform).

A controller 132 may be provided and coupled to various components of the processing platform 100 to control the operation thereof. The controller 132 can be a single controller that controls the entire processing platform 100, or multiple controllers that control individual portions of the processing platform 100. For example, the processing platform 100 may include separate controllers for each of the individual processing chambers 102, the central transfer station 112, the factory interface 128, and the robots 106.

In some embodiments, the controller 132 includes a central processing unit (CPU) 134, a memory 136, and support circuits 138. The controller 132 may control the processing platform 100 directly, or via computers (or controllers) associated with particular process chamber and/or support system components.

The controller 132 may be one of any form of general-purpose computer processor that can be used in an industrial setting for controlling various chambers and sub-processors. The memory 136 or computer readable medium of the controller 132 may be one or more of readily available memory such as random access memory (RAM), read only memory (ROM), floppy disk, hard disk, optical storage media (e.g., compact disc or digital video disc), flash drive, or any other form of digital storage, local or remote. The memory 136 can retain an instruction set that is operable by the processor (CPU 134) to control parameters and components of the processing platform 100.

The support circuits 138 are coupled to the CPU 134 for supporting the processor in a conventional manner. These circuits include cache, power supplies, clock circuits, input/output circuitry and subsystems, and the like. One or more processes may be stored in the memory 136 as software routine that, when executed or invoked by the processor, causes the processor to control the operation of the processing platform 100 or individual processing chambers in the manner described herein. The software routine may also be stored and/or executed by a second CPU (not shown) that is remotely located from the hardware being controlled by the CPU 134.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 132 has one or more configurations to execute individual processes or sub-processes to perform the method. The controller 132 can be connected to and configured to operate intermediate components to perform the functions of the methods. For example, the controller 132 can be connected to and configured to control one or more of gas valves, actuators, motors, slit valves, vacuum control or other components.

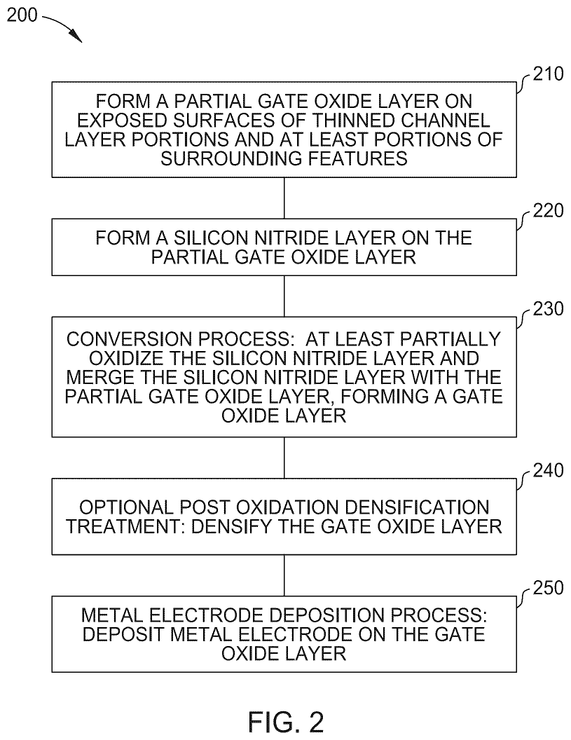

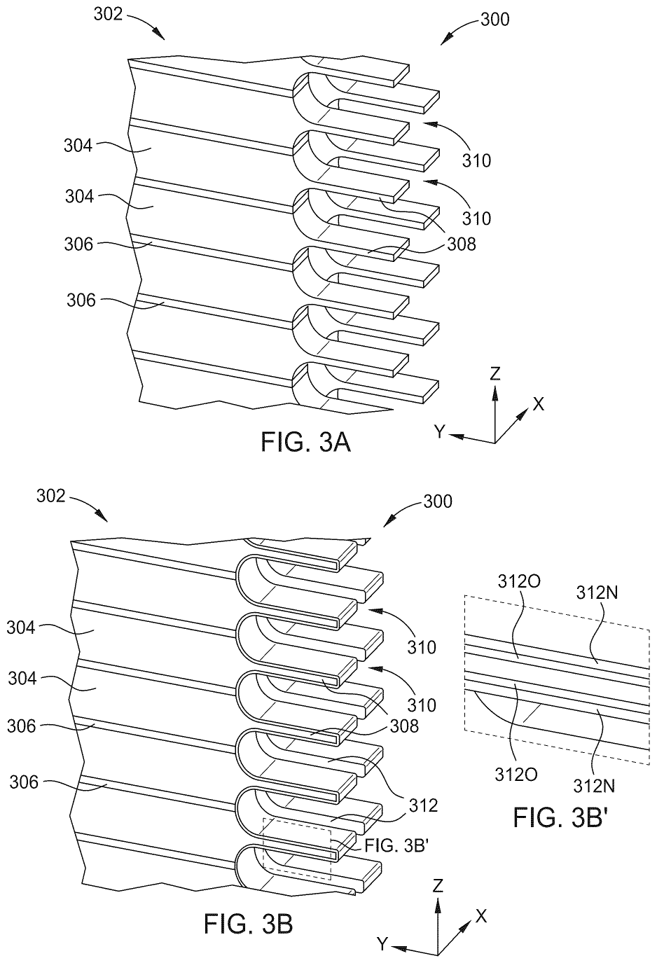

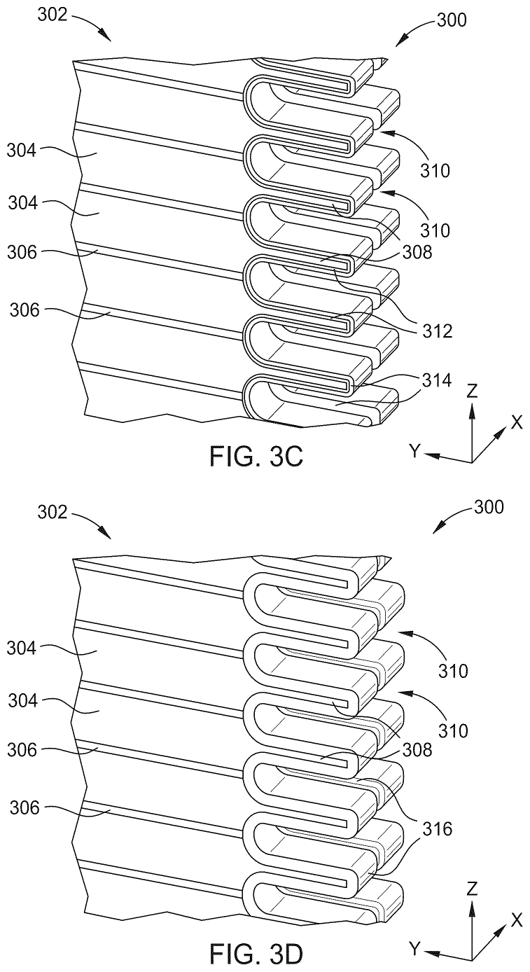

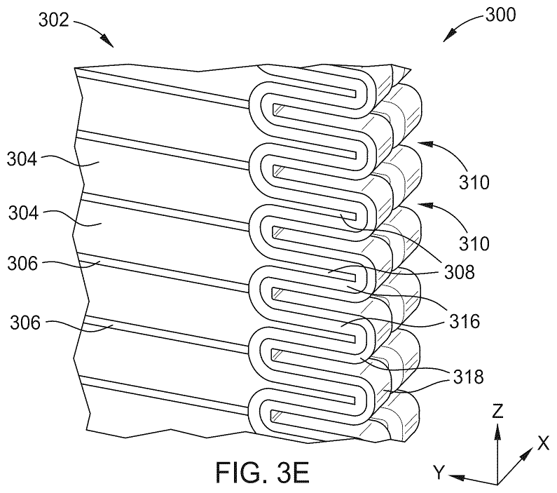

FIG. 2 is a process flow diagram of a method 200 of forming an oxide layer in a semiconductor structure 300 that may form a portion of lateral channels in a 3D dynamic random access memory (DRAM) device, according to one or more implementations of the present disclosure. FIGS. 3A, 3B, 3B′, 3C, 3D, and 3E are cross-sectional views of the semiconductor structure 300 corresponding to various stages of the method 200. Additionally, the method 200 may be used to form buried wordline (bWL) structures in 4F² DRAM cell transistor structure or other semiconductor devices, such as nanowires, that require a high-quality nitrogen-doped thin oxide layer in a high aspect ratio structure. Further, it should also be understood that the operations depicted in FIG. 2 may be performed simultaneously and/or in a different order than the order depicted in FIG. 2.

The semiconductor structure 300 includes fin-shaped columns 302 (one shown) formed on a substrate (not shown). The fin-shaped columns 302 each extend in the Y direction and are isolated from adjacent fin-shaped columns 302 in the X direction by a front inter-layer dielectric (ILD) (not shown). The fin-shaped columns 302 each include a stack of alternating channel layers 304 and sacrificial layers 306 in the Z direction and have a width in the X direction of between about 30 nm and about 150 nm. The fin-shaped columns 302 may be formed by epitaxially growing the stack of alternating channel layers 304 and sacrificial layers 306 on the substrate, and patterning the stack of alternating channel layers 304 and sacrificial layers 306.

The channel layers 304 may be formed of silicon (Si), each having a thickness of between about 3 nm and about 13 nm, for example, about 8 nm. The sacrificial layers 306 may be formed of silicon germanium (SiGe) with a ratio of germanium (Ge) ranging between about 10% and about 25%. The sacrificial layers 306 may each have a thickness of between about 3 nm and about 15 nm, for example, about 10 nm.

As shown in FIG. 3A, portions 308 of the channel layers 304 are thinned and lateral openings 310 are formed between the adjacent thinned channel layer portions 308. This thinning of the channel layers 304 may be performed by any wet etch process, performed in a processing station, such as one of the processing stations 108 shown in FIG. 1. The thinned channel layer portions 308 may have a thickness in the Z direction of about 3 nm and about 13 nm, a depth in the Y direction of between about 50 nm and about 200 nm, and spacing between the adjacent thinned channel layer portions 308 in the Z direction of between about 40 nm and about 90 nm.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100>, Si<110>, or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

In a conventional method of forming a nitrogen-doped gate oxide layer, silicon oxide is deposited by an ALD or a CVD process using a silicon containing precursor and an oxygen containing precursor in gas phases, and densified by anneal. Subsequently, nitrogen is incorporated in the silicon oxide by a remote plasma and a thermal method. The resultant silicon oxide has relatively low and non-uniform nitrogen incorporation. In particular, silicon oxide formed on inner surfaces of a high aspect ratio opening may have a large variation of nitrogen content on the inner surfaces of the opening.

In the embodiments described herein, the nitrogen-doped gate oxide layer is formed by first depositing a partial gate oxide layer, depositing a silicon nitride layer on the partial gate oxide layer, and then converting the deposited silicon nitride layer by a conversion process. Furthermore, nitrogen incorporation in the gate oxide layer is performed by an atomic layer deposition (ALD) process using nitrogen-containing process gas of a combination of nitrogen (N₂) and ammonia (NH₃) gases. By controlling content ratio of nitrogen (N₂) and ammonia (NH₃) gases, nitrogen content distribution (e.g., uniform over inner surfaces of a high aspect ratio opening) may be controlled and adjusted.

The method 200 begins in block 210, in which at least a portion of the gate oxide layer 316 (also referred to as a partial gate oxide layer) 312 is formed on exposed surfaces of the thinned channel layer portions 308 and at least portions of the surrounding features (e.g., remaining exposed inner surfaces of the lateral openings 310), as shown in FIG. 3B. The partial gate oxide layer 312 may be formed of silicon oxide (SiO₂) having a thickness of less than about 100 Å, by thermal oxidation growth, an atomic layer deposition (ALD) process, or combination of thermal oxide growth and ALD process, which may be performed in a processing station, such as one of the processing stations 108 shown in FIG. 1.

The partial gate oxide layer 312 may be a substantial thickness portion of the resulting gate oxide layer 316. For example, the resulting gate oxide layer 316 of thickness of about 80 Å is desired, the partial gate oxide layer 312 may be about 80 Å. The partial gate oxide layer 312 may include an oxide layer formed by ALD and an interlayer oxide layer of about 35 Å.

In some embodiments, the partial gate oxide layer 312 is formed by first forming a thin protective interlayer oxide 312O of silicon oxide (SiO₂) having a thickness of between about 5 Å and about 15 Å, by thermal oxidation growth, then depositing a silicon nitride layer 312N having a thickness of between about 5 Å and about 25 Å over the protective interlayer oxide 312O, by ALD, as shown in FIG. 3B′, and converting the silicon nitride layer 312N to the partial gate oxide layer 312, by a plasma radical oxidation process, such as remote plasma oxidation (RPO), or a thermal radical oxidation process, such as an in-situ steam generation (ISSG) process utilizing hydrogen (H₂) and oxygen (O₂) gases.

In some embodiments, the silicon nitride layer 312N has a concentration gradient of nitrogen varying from high concentration away from the protective interlayer oxide 312O to low concentration near the protective interlayer oxide 312O.

In some other embodiments, the silicon nitride layer 312N is a bi-layer of a bottom nitrogen-rich silicon nitride layer on the protective interlayer oxide 312O and a top silicon nitride layer on the bottom nitrogen-rich silicon nitride layer. The bottom nitrogen-rich silicon nitride layer may have nitrogen concentration of between about 15 atomic percent (at %) and about 60 at %, below stoichiometric concentration of silicon nitride (Si₃N₄). The top silicon nitride layer may have nitrogen concentration of between about 5 atomic percent (at %) and about 25 at %. The bottom nitrogen-rich silicon nitride layer may have a thickness of between about 5 Å and about 20 Å. The top silicon nitride layer may have a thickness of between about 5 Å and about 20 Å.

The bi-layer of the bottom nitrogen-rich silicon nitride layer and the top silicon nitride layer may be formed by an atomic layer deposition (ALD) process in two steps, in a processing station, such as one of the processing stations 108 shown in FIG. 1.

In the first step of the ALD process, the semiconductor structure 300 is exposed to a silicon-containing precursor and a nitrogen source, to form the bottom silicon nitride layer. The silicon-containing precursor may include silane (SiH₄), disilane (Si₂H₆), tetrasilane (Si₄H₁₀), or a combination thereof. The nitrogen source may be ammonia (NH₃) or nitrogen (N₂). In the second step of the ALD process, the semiconductor structure 300 is exposed to a silicon-containing precursor, to form the top silicon oxide layer. The silicon-containing precursor may include silane (SiH₄), disilane (Si₂H₆), tetrasilane (Si₄H₁₀), or a combination thereof.

In some other embodiments, the silicon nitride layer 312N is a hybrid layer of a bottom silicon nitride layer on the protective interlayer oxide 312O and a top silicon oxide layer on the bottom silicon nitride layer. The bottom silicon nitride layer may have a thickness of between about 5 Å and about 25 Å. The top silicon oxide layer may have a thickness of between about 5 Å and about 40 Å. The silicon nitride layer 312N may be a hybrid layer of a bottom silicon oxide layer on the protective interlayer oxide 312O and a top silicon nitride layer on the bottom silicon oxide layer.

The hybrid layer of the bottom silicon nitride layer and the top silicon oxide layer may be formed by an atomic layer deposition (ALD) process in two steps, in a processing station, such as one of the processing stations 108 shown in FIG. 1.

In the first step of the ALD process, the semiconductor structure 300 is exposed to a silicon-containing precursor and a nitrogen source, to form the bottom silicon nitride layer. The silicon-containing precursor may include silane (SiH₄), disilane (Si₂H₆), tetrasilane (Si₄H₁₀), or a combination thereof. The nitrogen source may be ammonia (NH₃) or nitrogen (N₂). In the second step of the ALD process, the semiconductor structure 300 is exposed to a silicon-containing precursor and oxygen source, to form the top silicon oxide layer. The silicon-containing precursor may include silane (SiH₄), disilane (Si₂H₆), tetrasilane (Si₄H₁₀), or a combination thereof. The oxygen source may include water (H₂O) or ozone (O₃).

In block 220, a silicon nitride capping layer 314 is formed on the partial gate oxide layer 312, as shown in FIG. 3C.

The silicon nitride capping layer 314 is formed by a plasma-enhanced atomic layer deposition (PE ALD) process, which may be performed in a processing station, such as one of the processing stations 108 shown in FIG. 1. Due to the nature of ALD, the silicon nitride capping layer 314 has a thickness conformal on the partial gate oxide layer 312. The silicon nitride capping layer 314 may be formed of silicon nitride (Si₃N₄) having a thickness of between about 5 Å and about 50 Å. In the ALD process, the semiconductor structure 300 is exposed to a silicon-containing precursor and a nitrogen source. The silicon-containing precursor may include silane (SiH₄), disilane (Si₂H₆), tetrasilane (Si₄H₁₀), or a combination thereof. The nitrogen source may be ammonia (NH₃) or nitrogen (N₂).

A PE ALD process, utilizing nitrogen-containing process gas, and carrier gas including argon (Ar) (100-60%), is performed for a plasma time of between 0 seconds and about 10 seconds, at a temperature of between about 300° C. and about 650° C. under a chamber pressure of between about 50 mTorr and about 20 Torr. The semiconductor structure 300 is exposed to dichlorosilane (DCS) gas for about 100 ms and about 5 sec. The nitrogen-containing process gas may include nitrogen (N₂) only, ammonia (NH₃) (0-20%) and nitrogen (N₂), or ammonia (NH₃) only. The use of nitrogen (N₂) gas, forming nitrogen radicals, and ammonia (NH₃) gas, forming amino radical (NH₂·), may result in different nitrogen content in a deposited silicon nitride layer. Thus, nitrogen content and/or nitrogen content distribution in a deposited silicon nitride layer may be controlled and adjusted at a predetermined nitrogen content distribution as desired, by choosing content ratios of nitrogen (N₂) and ammonia (NH₃) in the nitrogen-containing process gas.

A plasma generated from a microwave (MW) frequency generator may treat surfaces of the partial gate oxide layer 312 such that silicon (Si) atoms bond to the surfaces when the surfaces are exposed to the silicon-containing precursor (e.g., silane (SiH₄)), forming a Si—N—Si bonded silicon nitride layer.

After a cycle of a PE ALD process, one or more cycles are repeated with a purge of between 0 second and about 10 seconds between cycles, until a desired thickness of the silicon nitride capping layer 314 is achieved. In a PE ALD process, conformity of a deposited silicon nitride layer increases as a cycle is repeated.

In block 230, a conversion process is performed, in which the silicon nitride capping layer 314 is at least partially oxidized and merged with the partial gate oxide layer 312, forming a nitrogen-doped gate oxide layer 316, as shown in FIG. 3D. The resulting gate oxide layer 316 has nitrogen incorporation from the silicon nitride capping layer 314. The nitrogen distribution may be conformal at an interface between the partial gate oxide layer 312 and the silicon nitride capping layer 314. The nitrogen distribution can be designed to redistribute during this conversion process to form an optimized nitrogen profile depending on the electrical and diffusion barrier and characteristics as desired. The nitrogen concentration may be high (e.g., more than 5% or 2%) in the gate oxide layer 316.

The conversion process may include a plasma radical oxidation process, such as remote plasma oxidation (RPO), or a thermal radical oxidation process, such as an in-situ steam generation (ISSG) process utilizing hydrogen (H₂) and oxygen (O₂) gases. The conversion process may be performed in a processing station, such as one of the processing stations 108 shown in FIG. 1.

In a plasma radical oxidation process, oxygen radicals (O*) are directed to the silicon nitride capping layer 314 within the lateral openings 310, and thus the oxidation of the silicon nitride capping layer 314 occurs. In some embodiments, the plasma radical oxidation process may use an oxidizing agent including oxygen (O₂), nitric oxide (NO), nitrous oxide (N₂O), or the like, to provide oxygen radicals (O*). These may be used alone or in a combination thereof. Further, the plasma radical oxidation process may use a source gas for generating plasma including any combination of hydrogen (H₂) (of content ratio of 0% and about 80%), argon (Ar), helium (He), and xenon (Xe), among others. These may be used alone or in a combination thereof. In some embodiments, the plasma radical oxidation process may allow an oxidation reaction at a temperature of between about 900° C. and 1500° C. for a soak time of between about 3 seconds and about 3 minutes, to ensure high quality of the oxidized silicon.

In some embodiments, the plasma radical oxidation process may be performed under a pressure of between about 500 mTorr and about 10 Torr. The pressure may control an influx of the oxidizing agent introduced into the lateral openings 310. The influx of the oxidizing agent into the lateral openings 310 may be controlled also by applying a bias during the plasma radical oxidation process. Thus, a thickness and nitrogen content of the gate oxide layer 316 may be controlled and adjusted as desired, by adjusting oxidation temperature and oxidation time of the plasma radical oxidation process. For example, a plasma radial oxidation process at a higher oxidation temperature and a longer oxidation time duration leads to a thicker gate oxide layer 316. The nitrogen content increases with increased thickness of a silicon nitride capping layer 314 and nitrogen content increases with decreased oxidation time and decreased oxidation temperature.

The thermal radical oxidation process may be a combustion process utilizing H₂ and O₂ gases to provide oxygen radicals (O*), performed at a low pressure of about 10 Torr and at a temperature of between about 700° C. and about 1050° C.

In block 240, an optional post oxidation densification treatment is performed to densify (e.g., eliminate nitrogen and re-order bond structures within) the gate oxide layer 316.

The post oxidation densification treatment may be a plasma treatment, such as a decoupled plasma (DPHe) process and a remote plasma oxidation (RPO2) process, performed for between about 10 seconds and about 200 seconds, at a temperature of between about 400° C. and about 650° C.

In block 250, a metal electrode deposition process is performed, in which a metal electrode 318 is deposited on the gate oxide layer 316, as shown in FIG. 3E. The metal electrode deposition process may include any appropriate deposition process, such as chemical vapor deposition (CVD), or physical vapor deposition (PVD), performed in a processing station, such as one of the processing stations 108 shown in FIG. 1. The metal electrode 318 may be formed of titanium nitride (TiN), combination of titanium nitride (TiN) and tungsten (W), tungsten (W), or molybdenum (Mo).

It should be noted that the methods described herein can be applied to forming a gate oxide layer in vertical trench openings in 4F² DRAM devices, and a thin nanowire field-effect-transistor (FET) such as gate-all-around field-effect transistor (GAA FET) devices.

In the embodiments described herein methods of forming a high quality thin nitrogen-doped oxide layer in a semiconductor device, such as lateral channels in 3D dynamic random access memory (DRAM) device, vertical channels used in a 4F² DRAM device, and a thin nanowire field-effect-transistor (FET), are provided. In the methods described herein, a thin nitrogen-doped oxide layer may be formed first depositing a substantial portion of a gate oxide layer, depositing a silicon nitride layer on the substantial portion of the gate oxide layer, and then oxidizing the silicon nitride layer by a conversion process. The methods described herein for forming an oxide layer may allow incorporation of nitrogen at a high level (e.g., more than 5% or 2%) into a gate oxide layer and provide the capability of selectively tuning a thickness and nitride incorporation distribution of an oxide layer.

While the foregoing is directed to embodiments of the present disclosure, other and further embodiments of the disclosure may be devised without departing from the basic scope thereof, and the scope thereof is determined by the claims that follow.

1. A method for forming an oxide layer, comprising:
forming at least a portion of a gate oxide layer on inner surfaces of an opening;
forming a silicon nitride capping layer on the portion of the gate oxide layer; and
performing a conversion process to at least partially oxidize the silicon nitride capping layer, forming a nitrogen-doped gate oxide layer.

2. The method of claim 1, wherein the forming of the silicon nitride capping layer comprises a plasma-enhanced atomic layer deposition (PE ALD) process utilizing nitrogen-containing process gas.

3. The method of claim 2, wherein the nitrogen-containing process gas comprises at least one of nitrogen (N₂) gas or ammonia (NH₃) gas.

4. The method of claim 1, further comprising:
performing a densification treatment to densify the nitrogen-doped gate oxide layer,
wherein the densification treatment is a decoupled plasma process or a remote plasma oxidation process.

5. The method of claim 1, wherein:
the silicon nitride capping layer comprises silicon nitride (Si₃N₄) having a thickness of between 5 Å and 50 Å, and
the portion of the gate oxide layer comprises silicon oxide (SiO₂) having a thickness of less than 100 Å.

6. The method of claim 1, wherein the opening is either a lateral opening or a vertical trench opening.

7. The method of claim 1, wherein the conversion process comprises a plasma radical oxidation process utilizing an oxidizing agent including oxygen (O₂) and a source gas including any combination of hydrogen (H₂), argon (Ar), and helium (He).

8. The method of claim 1, wherein the conversion process comprises in-situ steam generation (ISSG) process utilizing hydrogen (H₂) and oxygen (O₂) gases.

9. A method for forming an oxide layer, comprising:
forming at least a portion of a gate oxide layer on inner surfaces of an opening, comprising:
forming protective interlayer oxide on the inner surfaces of the opening;
forming a bi-layer of a bottom nitrogen-rich silicon nitride layer on the protective interlayer oxide and a top silicon nitride layer on the bottom nitrogen-rich silicon nitride layer; and
oxidizing the bi-layer.

10. The method of claim 9, wherein the forming of the bi-layer comprises an atomic layer deposition (ALD) process.

11. The method of claim 9, wherein:
the opening is either a lateral opening or a vertical trench opening,
the bottom nitrogen-rich silicon nitride layer has nitrogen concentration of between 15 atomic percent (at %) and 60 at %, and the top silicon nitride layer has nitrogen concentration of between 5 atomic percent (at %) and 25 at %, and
the protective interlayer oxide comprises silicon oxide (SiO₂) having a thickness of between 5 Å and 15 Å.

12. The method of claim 9, further comprising:
forming a silicon nitride capping layer on the portion of the gate oxide layer;
performing a conversion process to at least partially oxidize the silicon nitride capping layer and merge the silicon nitride capping layer with the portion of the gate oxide layer, forming a nitrogen-doped gate oxide layer; and
performing a densification process to densify the nitrogen-doped gate oxide layer.

13. The method of claim 12, wherein the conversion process comprises a plasma radical oxidation process utilizing an oxidizing agent including oxygen (O₂) and a source gas including any combination of hydrogen (H₂), argon (Ar), and helium (He).

14. The method of claim 12, wherein the conversion process comprises in-situ steam generation (ISSG) process utilizing hydrogen (H₂) and oxygen (O₂) gases and a source gas including any combination of hydrogen (H₂), argon (Ar), and helium (He).

15. A method for forming an oxide layer, comprising:
forming at least a portion of a gate oxide layer on inner surfaces of an opening, comprising:
forming protective interlayer oxide on the inner surfaces of the opening;
forming a hybrid layer of a bottom silicon nitride layer on the protective interlayer oxide and a top silicon oxide layer on the bottom silicon nitride layer; and
oxidizing the hybrid layer.

16. The method of claim 15, wherein the forming of the hybrid layer comprises an atomic layer deposition (ALD) process.

17. The method of claim 15, wherein:
the opening is either a lateral opening or a vertical trench opening,
the bottom silicon nitride layer has a thickness of between 5 Å and 20 Å, and the top silicon oxide layer has a thickness of between 5 Å and 20 Å, and
the protective interlayer oxide comprises silicon oxide (SiO₂) having a thickness of between 5 Å and 15 Å.

18. The method of claim 15, further comprising:
forming a silicon nitride capping layer on the portion of the gate oxide layer;
performing a conversion process to at least partially oxidize the silicon nitride capping layer and merge the silicon nitride capping layer with the portion of the gate oxide layer, forming a nitrogen-doped gate oxide layer; and
performing a densification process.

19. The method of claim 18, wherein the conversion process comprises a plasma radical oxidation process utilizing an oxidizing agent including oxygen (O₂) and a source gas including any combination of hydrogen (H₂), argon (Ar), and helium (He).

20. The method of claim 18, wherein the conversion process comprises in-situ steam generation (ISSG) process utilizing hydrogen (H₂) and oxygen (O₂) gases and a source gas including any combination of hydrogen (H₂), argon (Ar), and helium (He).
